(19) United States
(12) Patent Application Publication
(10) Pub. No.: US 2026/0114334 A1
(43) Pub. Date: Apr. 23, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: Sang Hyun Jin, Incheon (KR); In Soo Choi, Seoul (KR); Ki Yeul Yang, Incheon (KR)

(73) Assignee: Amkor Technology Singapore Holding Pte. Ltd., (omitted)

(21) Appl. No.: 18/922,211

(22) Filed: Oct. 21, 2024

(51) Int. Cl. H01L 23/498; H01L 23/00; H01L 23/31; H01L 25/065

(52) U.S. Cl. CPC H10W 90/701; H10W 74/117; H10W 90/00; H10W 70/09; H10W 70/60; H10W 70/6528

(57) ABSTRACT

In one example, an electronic device includes a substrate and a first dielectric disposed over the substrate. The first dielectric defining first trace openings. A first conductive pattern can be disposed in the trace openings and recessed from an upper side of the first dielectric. The first conductive pattern includes first traces. A second conductive pattern can be disposed over the upper side of the first dielectric. The second conductive pattern can include second traces staggered over the first traces. A second dielectric can be disposed over the second conductive pattern and extending to the first traces in the trace openings. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2N show an example method for manufacturing an electronic device using cross-sectional views.

FIG. 3 shows a cross-sectional view of an example electronic device.

FIG. 4 shows a cross-sectional view of an example electronic device.

FIG. 5 shows a cross-sectional view of an example electronic device.

FIG. 6A to 6E show an example method for manufacturing an electronic device using cross-sectional views.

FIG. 7 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence or addition of one or more other features.

The terms “first,” “second,” etc. may be used herein to describe various elements. These elements are not limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical coupling or an electrical coupling.

### DESCRIPTION

An example electronic device includes a substrate and a first dielectric disposed over the substrate. The first dielectric defining first trace openings. A first conductive pattern can be disposed in the trace openings and recessed from an upper side of the first dielectric. The first conductive pattern includes first traces. A second conductive pattern can be disposed over the upper side of the first dielectric. The second conductive pattern can include second traces staggered over the first traces. A second dielectric can be disposed over the second conductive pattern and extending to the first traces in the trace openings.

Another example electronic device can include a substrate and a first dielectric disposed over the substrate. The first dielectric can define first trace openings. A first conductive pattern can be disposed in the first trace openings and recessed from an upper side of the first dielectric. The first conductive pattern can include first traces. A second conductive pattern can be disposed over the upper side of the first dielectric cand can include second traces staggered over the first traces. A second dielectric can be disposed over the second conductive pattern and extending to the first conductive pattern in the trace openings. A third dielectric can be disposed over the second dielectric. The third dielectric can define second trace openings. A third conductive pattern can be disposed in the second trace openings and recessed from an upper side of the third dielectric. The third conductive pattern can include third traces. A fourth conductive pattern can be disposed over the upper side of the third dielectric. The fourth conductive pattern can include fourth traces staggered over the third traces. A fourth dielectric can be disposed over the fourth conductive pattern and can extend to the third traces in the trace openings.

An example method of manufacturing an electronic device can include the steps of providing a substrate, providing a first dielectric over the substrate, and providing a first conductive pattern in the first trace openings. The first dielectric defines first trace openings, and the first conductive pattern can be recessed from an upper side of the first dielectric. The first conductive pattern can include first traces. A second conductive pattern can be provided over the upper side of the first dielectric. The second conductive pattern can include second traces staggered over the first traces. A second dielectric can be provided over the second conductive pattern. The second dielectric can extend to the first traces in the first trace openings.

Other examples are included in the present disclosure. Such examples may be found in the figures, in the claims, or in the description of the present disclosure.

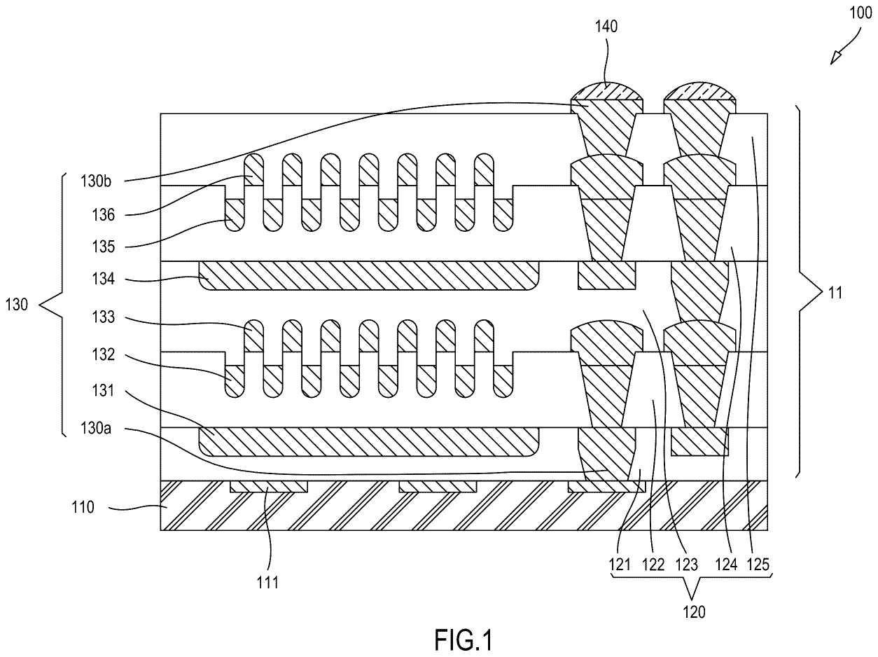

FIG. 1 shows a cross-sectional view of an example electronic device 100. In the example shown in FIG. 1, electronic device 100 comprises electronic component 110 and redistribution layer (RDL) substrate 11. RDL substrate 11 comprises dielectric structure 120 and conductive structure 130. In some examples, electronic device 100 can also include interconnects 140.

In accordance with various examples, dielectric structure 120 can comprise first dielectric 121, second dielectric 122, third dielectric 123, fourth dielectric 124, and fifth dielectric 125. Conductive structure 130 can comprise first conductive pattern 131, second conductive pattern 132, third conductive pattern 133, fourth conductive pattern 134, fifth conductive pattern 135, and sixth conductive pattern 136. Conductive structure 130 can comprise inward terminals 130a and outward terminals 130b. Inward terminals 130a can be coupled to component interconnects 111 of electronic component 110.

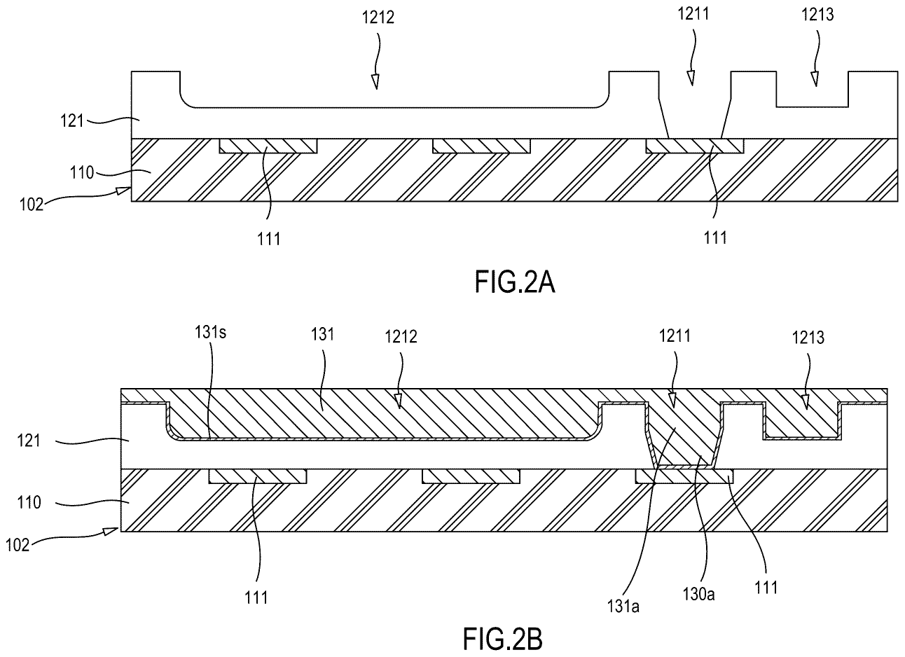

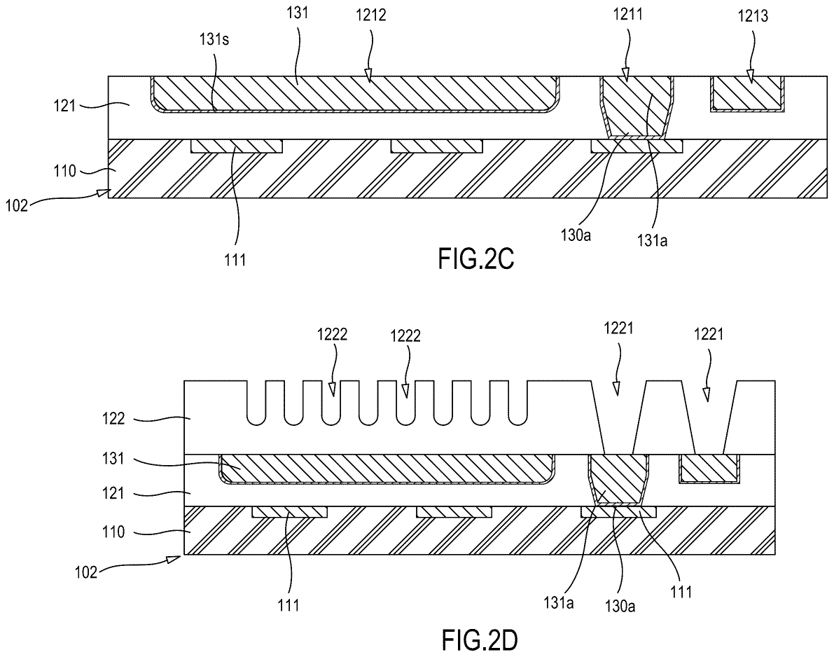

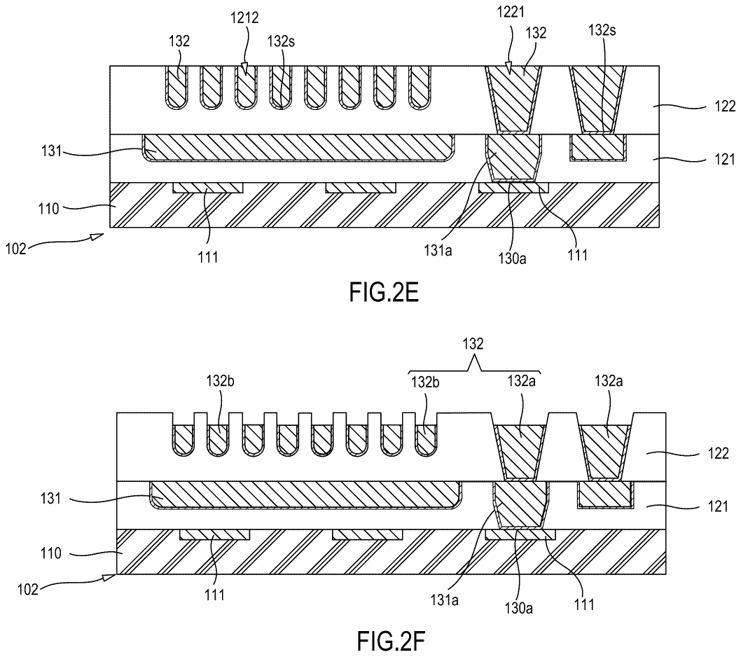

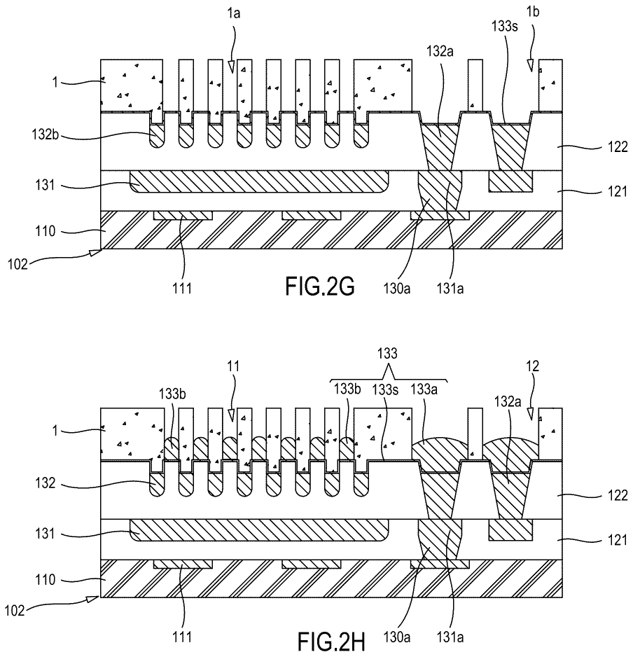

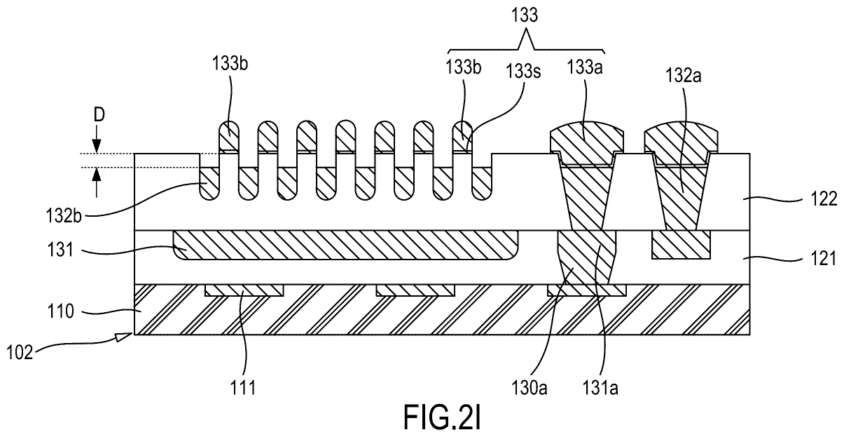

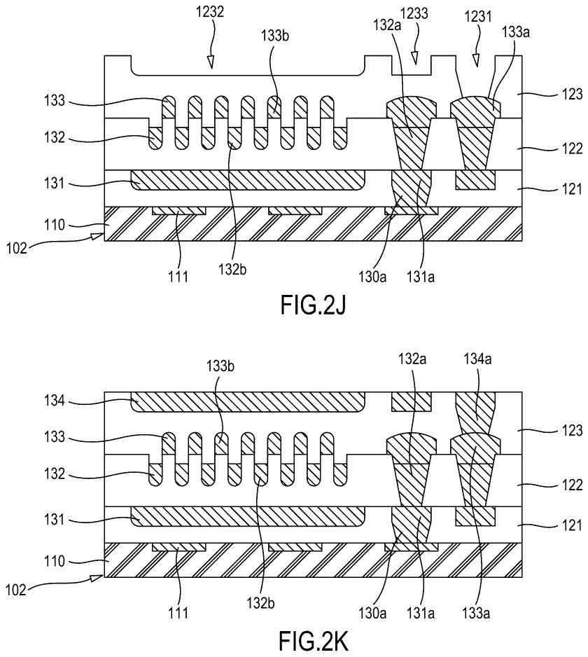

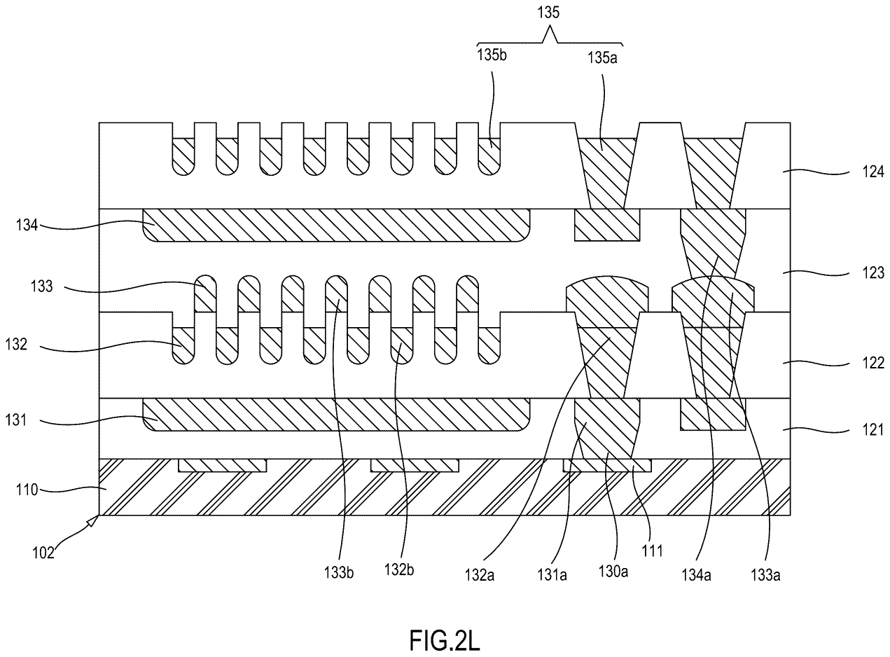

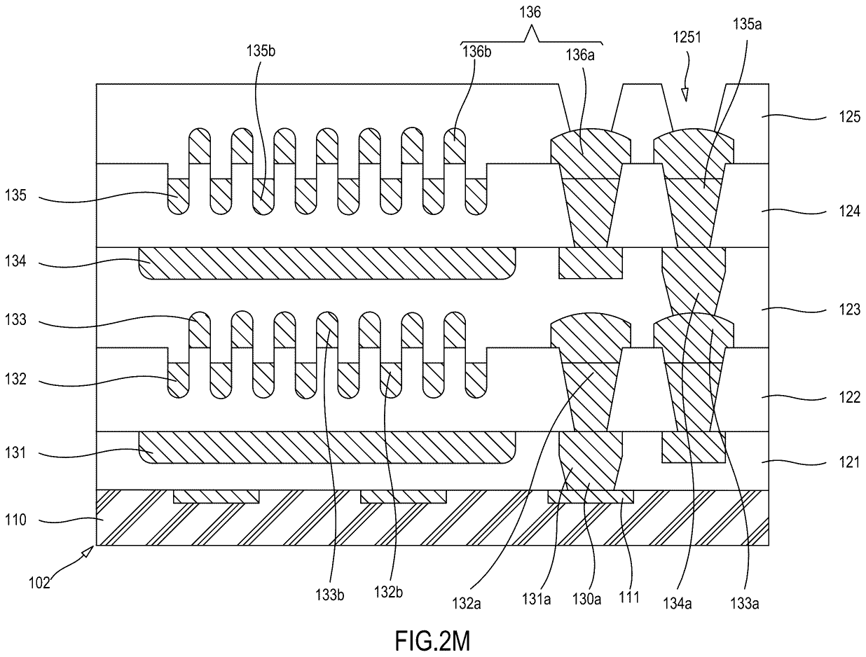

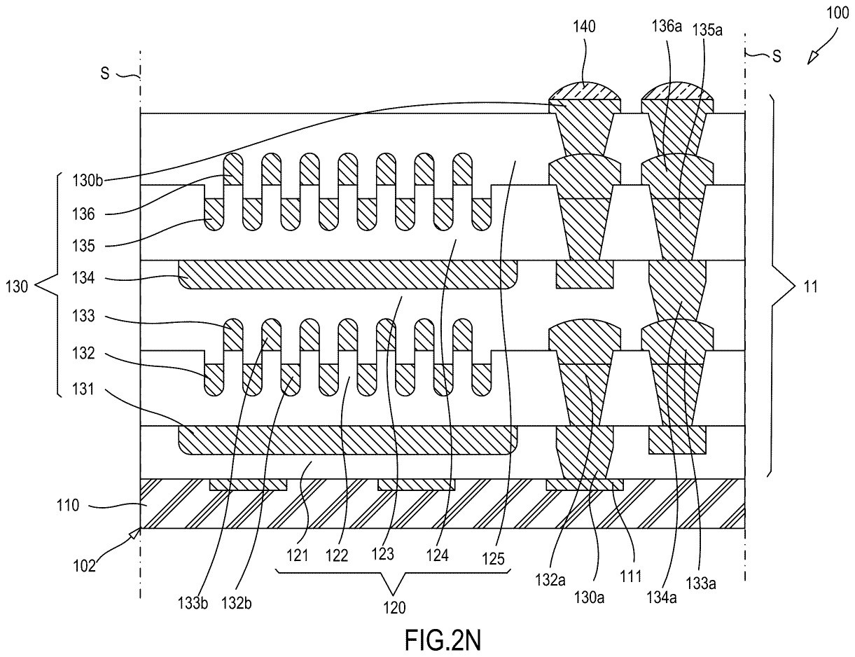

FIGS. 2A to 2N show cross-sectional views of an example method for manufacturing an electronic device, such as electronic device 100 of FIG. 1. FIG. 2A shows a cross-sectional view of electronic device 100 at an early stage of manufacture. In the example shown in FIG. 2A, first dielectric 121 can be provided on electronic component 110. Electronic component 110 can comprise or be referred to as a semiconductor die, a semiconductor chip, or package. For example, electronic component 110 can comprise a digital signal processor, network processor, power management unit, audio processor, radio-frequency circuit, wireless baseband system-on-chip (SoC) processor, sensor, or application specific integrated circuit (ASIC). In some examples, electronic component 110 can be configured to perform calculations, control processing, store data, or remove noise from electrical signals.

Electronic component 110 can comprise component interconnects 111. Component interconnects 111 can be disposed over an active side of electronic component 110. Component interconnects 111 can comprise or be referred to as pads, lands, UBMs (Under Bump Metals), studs, bumps, or pillars.

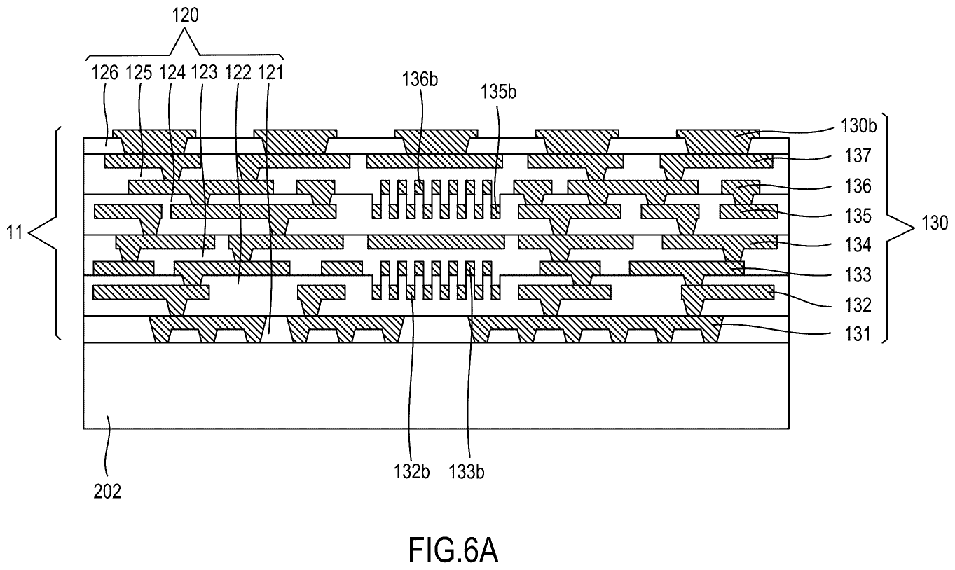

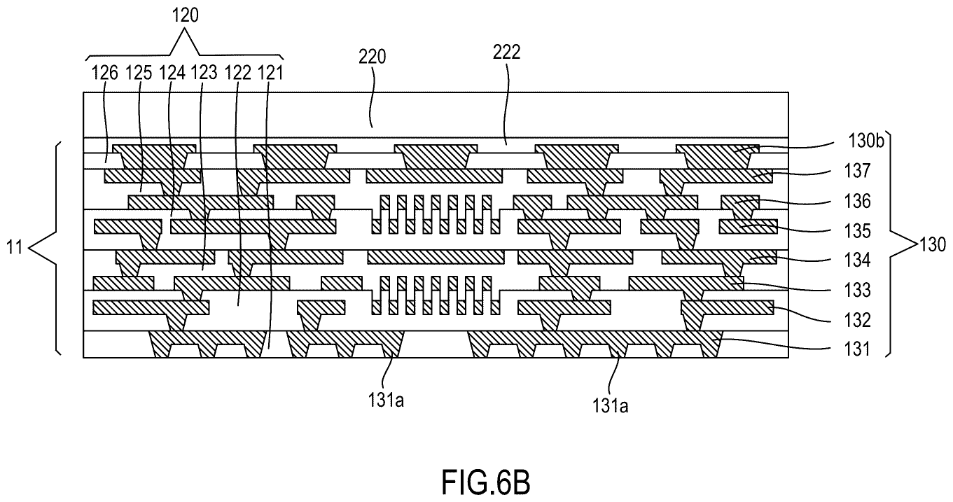

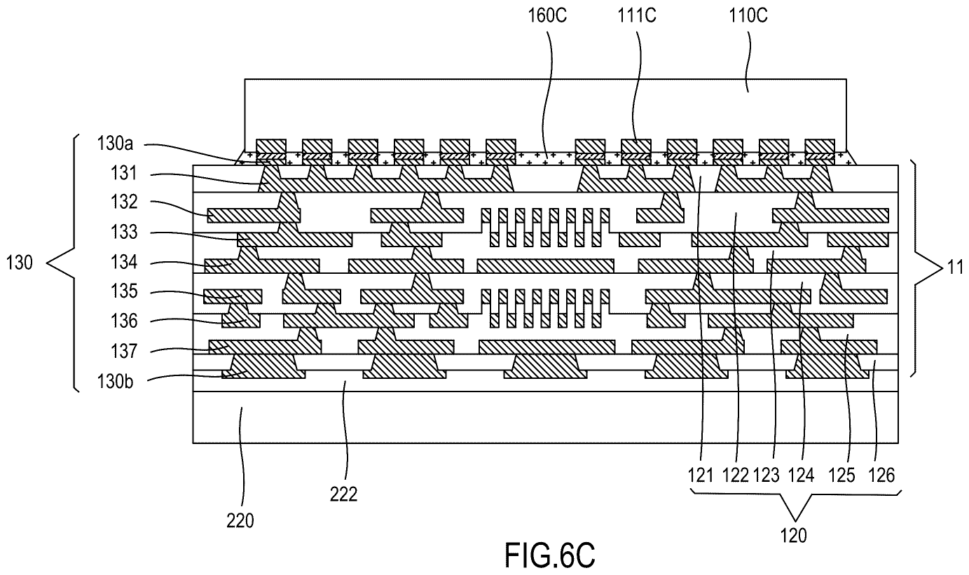

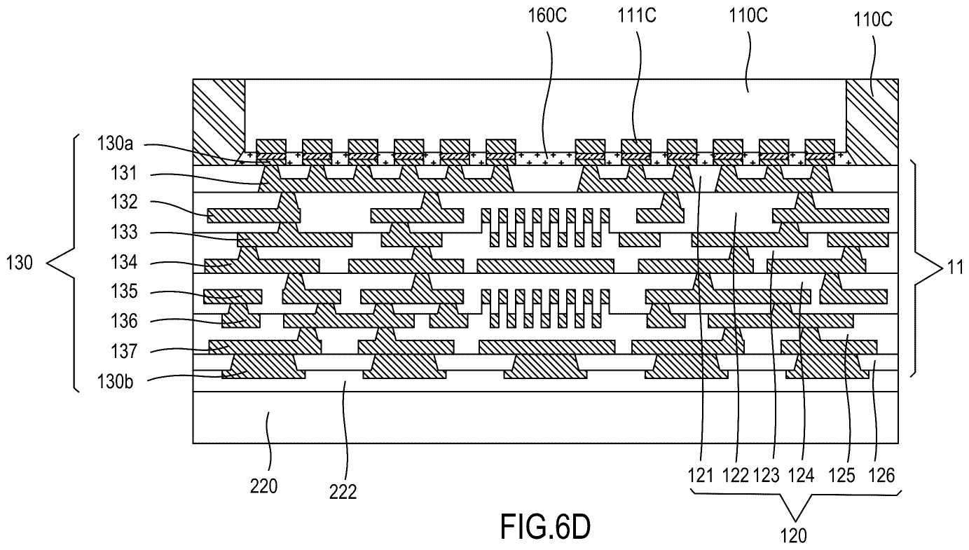

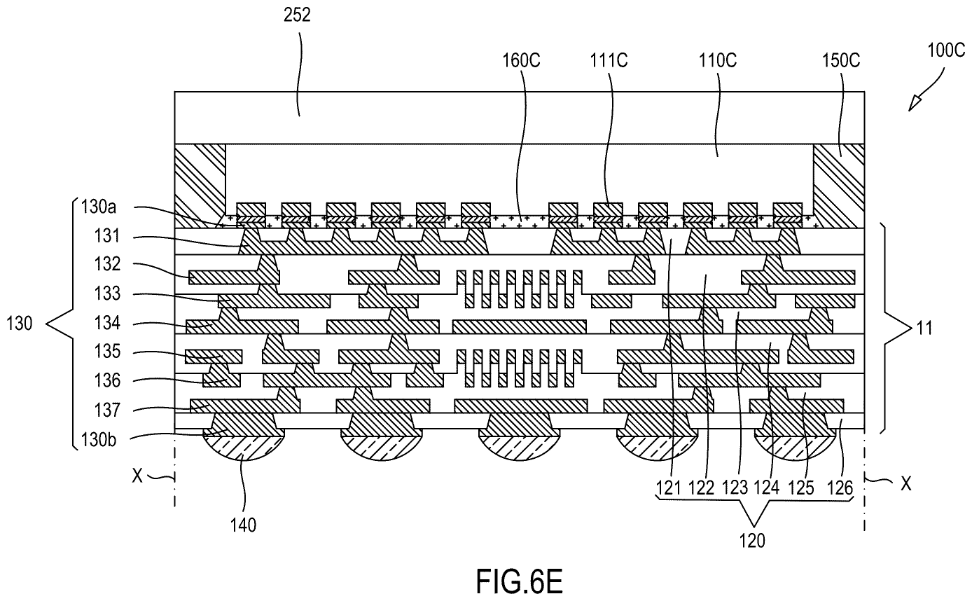

In accordance with various examples, electronic component 110 can be part of a substrate 102. In some examples, substrate 102 can comprise or be referred to as a wafer, a reconstituted wafer, or a panel. For example, substrate 102 can be a semiconductor wafer including a plurality of electronic components 110 formed in rows and columns across the wafer and separated by saw streets. In some examples, substrate 102 can be a reconstituted wafer including a plurality of known good electronic components 110 arranged in rows and columns with encapsulant located between adjacent known good electronic components 110. In some examples, substrate 102 can be a panel including one or more semiconductor wafers and/or reconstituted wafers located thereon. The thickness of substrate 102 can range from about 20 micrometers (μm) to about 1000 μm. The terms about, approximately, or similar terms as used herein with numeric values can mean +/−5%, +/−10%, +/−15%, +/−20%, or +/−25%. In some examples, substrate 102 can be a temporary carrier, as discussed below with reference to FIG. 6A.

In accordance with various examples, first dielectric 121 can be provided to cover the upper side of substrate 102. First dielectric 121 can be formed by physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), spin coating, spray coating, dip coating, rod coating, or any other suitable deposition process.

First dielectric 121 can be patterned to provide one or more openings 1211, trace groove(s) 1212, and pad groove(s) 1213 in first dielectric 121. Openings 1211 can extend completely through first dialectic 121 and can expose component interconnects 111. Trace groove(s) 1212 and pad groove(s) 1213 can be formed partially through first dielectric 121, such that a portion of first dielectric 121 remains over electronic component 110 and forms a floor of trace groove(s) 1212 and pad groove(s) 1213. The layout and shape of trace groove(s) 1212 and pad groove(s) 1213 are selected to form the desired conductive structures (e.g., traces, pads, ground planes, etc.) of conductive pattern 131 (FIG. 2B).

In some examples, first dielectric 121 can be patterned by providing a patterned mask (e.g., a patterned photoresist) on the upper side of first dielectric 121. Portions of first dielectric 121 exposed from the mask are then removed to form openings 1211, trace groove(s) 1212, and pad groove(s) 1213. The mask is removed after first dielectric 121 is patterned.

In some examples, first dielectric 121 can comprise one or more layers of an electrical insulating material, such as an organic dielectric (e.g., polymer, polyimide (PI), benzocyclobutene (BCB), polybenzoxazole (PBO), bismaleimide triazine (BT)) or an inorganic dielectric (e.g., silicon nitride (Si3N4), silicon oxide (SiO2), or silicon oxynitride (SiON)). In some examples, the thickness of first dielectric 121 can range from about 2 μm to about 20 μm.

FIG. 2B shows a cross-sectional view of electronic device 100 at a later stage of manufacture. In the example shown in FIG. 2B, first conductive pattern 131 can be provided over first dielectric 121. First conductive pattern 131 can be located in and/or fill openings 1211, trace groove(s) 1212, and pad groove(s) 1213.

In some examples, first conductive pattern 131 can be provided by forming a seed layer 131s covering the upper side of first dielectric 121. For example, seed layer 131s can be provided over the upper most surface of first dielectric 121, the sidewalls and floors of openings 1211; trace groove(s) 1212; and pad groove(s) 1213, and along the exposed upper side of component interconnects 111. Seed layer 131s can be formed by electroless plating, electrolytic plating, sputtering, PVD, CVD, MOCVD, ALD, LPCVD, PECVD, or any other suitable deposition process and can comprise one or more layers of titanium (Ti), titanium tungsten (TiW), tungsten (W), chromium (Cr), aluminum (Al), nickel (Ni), gold (Au), silver (Ag), or copper (Cu). In some examples, the thickness of seed layer 131s can range from about 0.01 μm to about 1 μm. Electrically conductive material (e.g., Cu, Al, Au, Ag, or Ni) can be provided over seed layer 131s by electroless plating, electrolytic plating, sputtering, PVD, CVD, MOCVD, ALD, LPCVD, PECVD, or any other suitable deposition.

FIG. 2C shows a cross-sectional view of electronic device 100 at a later stage of manufacture. In the example shown in FIG. 2C, first conductive pattern 131 is planarized to remove portions of first conductive pattern 131 located outside of openings 1211, trace groove(s) 1212, and pad groove(s) 1213. In some examples, chemical mechanical planarization (CMP) can be used to remove first conductive pattern 131 from over the upper most surface of first dielectric 121. After the CMP process, the upper side of first conductive pattern 131 can be coplanar with the upper side of first dielectric 121. The thickness of first conductive pattern 131 can range from about 1 μm to about 20 μm. In some examples, first conductive pattern 131 can comprise or be referred to as an embedded trace RDL. For example, the upper side of first conductive pattern 131 can be coplanar with or recessed with respect to the upper side of first dielectric 121.

First conductive pattern 131 can comprise or be referred to as traces, pads, vias, ground plane(s), wiring pattern(s), or circuit pattern(s). In accordance with various examples, the portions of first conductive pattern 131 that are located in openings 1211 can be coupled to component interconnects 111 of electronic device 110 and can comprise or be referred to as first conductive vias 131a. The thickness of first conductive vias 131a can be similar or equal to the thickness of first dielectric 121. The portions of first conductive pattern 131 located at the floor of openings 1211 (i.e., at the bottom sides of first conductive vias 131a) can be referred to as substrate inward terminals 130a. In some examples, one or more of the trace groove(s) 1212 and the portion(s) of first conductive pattern 131 located in the trace groove(s) 1212 can comprise and/or form one or more ground plane(s).

FIG. 2D shows a cross-sectional view of electronic device 100 at a later stage of manufacture. In the example shown in FIG. 2D, second dielectric 122 can be provided on first conductive pattern 131 and first dielectric 121. In some examples, second dielectric 122 can be provided covering first conductive pattern 131 and first dielectric 121. Portions of second dielectric 122 can be removed (i.e., second dielectric 122 can be patterned) to form openings 1221 and trace grooves 1222. Trace grooves 1222 and openings 1221 can be formed by etching (e.g., wet etching or dry etching), laser ablation, or any other suitable patterning process. In accordance with various embodiments, trace grooves 1222 can extend partially through second dielectric 122, such that a portion of second dielectric 122 remains over first dielectric 121 and first conductive pattern 131 and forms a floor of trace grooves 1222. Openings 1221 can extend completely through second dielectric 122 and can expose portions of first conductive pattern 131. In some examples, second dielectric 122 can have elements, features, materials, or manufacturing methods similar to those of first dielectric 121.

FIG. 2E shows a cross-sectional view of electronic device 100 at a later stage of manufacture. In the example shown in FIG. 2E, second conductive pattern 132 can be provided over second dielectric 122 and first conductive pattern 131. Second conductive pattern 132 can be located in and/or fill openings 1221 and trace grooves 1222. Second conductive pattern 132 can have elements, features, materials, or manufacturing methods similar to those of first conductive pattern 131.

In accordance with various examples, second conductive pattern 132 can be provided by forming seed layer 132s covering the upper side of second dielectric 122, similar to seed layer 131s. Seed layer 132s can be provided along the upper-most surface of second dielectric 122, the sidewalls and floors of openings 1221 and trace grooves 1222, and along the exposed upper side of first conductive pattern 131. Seed layer 132s can be formed by electroless plating, electrolytic plating, sputtering, PVD, CVD, MOCVD, ALD, LPCVD, PECVD, or any other suitable deposition process. See layer 132s can comprise one or more layers of Ti, TiW, W, Cr, Al, Ni, Au, Ag, or Cu. In some examples, the thickness of seed layer 132s can range from about 0.01 μm to about 1 μm. Electrically conductive material (e.g., Cu, Al, Au, Ag, or Ni) can be provided over seed layer 132s by electroless plating, electrolytic plating, sputtering, PVD, CVD, MOCVD, ALD, LPCVD, PECVD, or any other suitable deposition.

Second conductive pattern 132 can then be planarized to remove portions of second conductive pattern 132, including seed layer 132s, located outside of openings 1221 and trace grooves 1222. In some examples, CMP can be used to remove second conductive pattern 132 from over the uppermost surface of second dielectric 122. After the CMP process, the upper side of second conductive pattern 132 can be coplanar with the upper side of second dielectric 122.

FIG. 2F shows a cross-sectional view of electronic device 100 at a later stage of manufacture. In the example shown in FIG. 2F, a portion of the upper side of second conductive pattern 132 can be removed through, for example, etching or laser ablation. In response to the removal, the upper side of second conductive pattern 132 can lower than the uppermost side of second dielectric 122. For example, the upper side of second conductive pattern 132 can be recessed relative to the upper side of second dielectric 122. In some examples, the height difference between the upper side of second conductive pattern 132 and the upper side of second dielectric 122 can range from about 2 μm to about 20 μm, from about 3 μm to about 15 μm, or from about 5 μm to about 10 μm.

Second conductive pattern 132 can comprise or be referred to as traces, pads, vias, wiring pattern(s), or circuit pattern(s). In accordance with various examples, the portions of second conductive pattern 132 that are located in openings 1221 can be coupled to and can contact the upper side of first conductive pattern 131 and can comprise or be referred to as second conductive vias 132a. Second conductive pattern 132 can be electrically coupled to electronic component 110 via first conductive pattern 131 (e.g., via first conductive vias 131a). The thickness of second conductive vias 132a can be less than the thickness of second dielectric 122. The portions of second conductive pattern 132 located in trace grooves 1222 can comprise or be referred to as embedded traces 132b.

In some examples, the thickness of second conductive pattern 132 can range from about 0.1 μm to about 20 μm. In some examples, the width of embedded traces 132b can range from about 0.5 μm to about 10 μm, about 1.0 μm to about 5 μm, or about 1.5 μm to about 2.5 μm. The line spacing of embedded traces 132b (i.e., the distance between adjacent embedded traces 132b) can range from about 0.5 μm to about 10 μm, about 1.0 μm to about 5 μm, or about 1.5 μm to about 2.5 μm. In some examples, embedded traces 132b can have a width of approximately 2.0 μm and a line spacing of approximately 2.0 μm. In some examples, embedded traces 132b can have a width of approximately 1.0 μm and a line spacing of approximately 1.0 μm.

FIG. 2G shows a cross-sectional view of electronic device 100 at a later stage of manufacture. In the example shown in FIG. 2G, seed layer 133s of third conductive pattern 133 (FIG. 2H) can be provided over second conductive pattern 132 and second dielectric 122. Seed 133s can cover the upper side of second dielectric 122 and the upper side of second conductive pattern 132. The thickness of seed 133s is smaller than the height difference between the upper side of second conductive pattern 132 and the upper side of second dielectric 122. In accordance with various examples, the elements, features, materials, or manufacturing methods of seed 133s can be similar to or the same as those of seed 131s and/or seed 132s. Seed layer 133s of FIG. 2G is omitted from some figures depicting subsequent processing steps for simplicity (e.g., FIGS. 2J-2N), though it should be understood that seed layer 133s can be present in the examples of subsequent figures even where not depicted.

In accordance with various embodiments, mask 1 is provided over seed 133s, second conductive pattern 132, and second dielectric 122. In some examples, mask 1 can comprise a photo resist. Mask 1 can be patterned through, for example, exposure, development, etching, and curing to provide mask openings 1a and 1b. Mask openings 1a and 1b can expose portions of seed 133s. Mask openings 1a can expose portions of seed 133s located on second dielectric 122 and can comprise or be referred to as trace openings or trace grooves. Mask openings 1b can expose portions of seed 133s located on second conductive vias 132a and can comprise or be referred to as pad openings. In some examples, the width or diameter of mask openings 1b can be greater than the width or diameter of second conductive vias 132a, such that mask openings 1b also expose portions of seed 133s located on the upper side of second dielectric 122.

FIG. 2H shows a cross-sectional view of electronic device 100 at a later stage of manufacture. In the example shown in FIG. 2H, electrically conductive material (e.g., Cu, Al, Au, Ag, or Ni) of third conductive pattern 133 can be provided in mask openings 1a and 1b. The electrically conductive material can be coupled to and contact seed layer 133s. The electrically conductive material can be provided by electroless plating, electrolytic plating, sputtering, PVD, CVD, MOCVD, ALD, LPCVD, PECVD, or any other suitable deposition. The portions of third conductive pattern 133 located in mask openings 1b can be coupled to and can contact the upper side of second conductive pattern 132 (e.g., coupled to the upper side of second conductive vias 132a) and can comprise or be referred to as conductive pads 133a. The portions of third conductive pattern 133 located in mask openings 1a can comprise or be referred to as traces 133b. The thicknesses of third conductive pattern 133 can range from about 0.1 μm to about 20 μm. The thickness of conductive pad 133a can be greater than the thickness of traces 133b, as conductive pad 133a extends into second dielectric 122 to contact and couple to second conductive via 132a.

FIG. 2I shows a cross-sectional view of electronic device 100 at a later stage of manufacture. In the example shown in FIG. 2I, mask 1 and the portions of seed 133s not covered by traces 133b or pads 133a are removed. In some examples, third conductive pattern 133 can comprise or be referred to as a semi-additive process (SAP) RDL. For example, third dielectric 123 (FIG. 2J), which surrounds and/or contacts the lateral and upper sides of traces 133b, is provided after third conductive pattern 133 is formed.

In some examples, the width of traces 133b can range from about 0.5 μm to about 10 μm, about 1.0 μm to about 5 μm, or about 1.5 μm to about 2.5 μm. The line spacing of traces 133b (i.e., the distance between adjacent traces 133b) can range from about 0.5 μm to about 10 μm, about 1.0 μm to about 5 μm, or about 1.5 μm to about 2.5 μm. In some examples, traces 133b can have a width of approximately 2.0 μm and a line spacing of approximately 2.0 μm. In some examples, traces 133b can have a width of approximately 1.0 μm and a line spacing of approximately 1.0 μm.

In some examples, traces 133b of third conductive pattern 133 may be located between and generally staggered vertically relative to the traces 132b of second conductive pattern 132. Traces 133b can be substantially non-overlapping with traces 132b. As used herein, the phrase substantially non-overlapping can mean that the traces 133b are oriented between adjacent traces 132b in a horizontal direction and disposed a distance D above or below traces 132b in a vertical direction, with traces 132b disposed outside a footprint of traces 133b. Substantially non-overlapping traces can overlap slightly, with a trace 132b extending into a footprint of another traces 133b in some examples as a result of manufacturing tolerances or imperfections, for example.

In some examples, a distance D can be between and can vertically separate the lower side of traces 133b and the upper side of traces 132b. Traces 133b and 132b located laterally between each other and separated vertically can increase integration and density of the conductive patterns. Increasing the density using the above-described staggering techniques can decrease package thickness as compared to packages with the same number of redistribution layers (e.g., two redistribution layers and a ground plane layer) without staggering. Some examples using the staggered traces described herein can increase the number of redistribution layers as compared to packages having same or similar dimensions but without staggering.

FIG. 2J shows a cross-sectional view of electronic device 100 at a later stage of manufacture. In the example shown in FIG. 2J, third dielectric 123 can be provided over third conductive pattern 133, second conductive pattern 132, and second dielectric 122. Third dielectric 123 can cover and contact the upper sides of traces 132b and the upper and lateral sides of traces 133b and pads 133a. In accordance with various examples, the elements, features, materials, or manufacturing methods of third dielectric 123 can be similar to or the same as those of first dielectric 121.

First dielectric 121 can be patterned to provide one or more openings 1231, trace groove(s) 1232, and pad groove(s) 1233 in third dielectric 123. Openings 1231 can extend completely through third dialectic 123 and can expose pads 133a of third conductive pattern 133. Trace groove(s) 1232 and pad groove(s) 1233 can be formed partially through third dielectric 123, such that a portion of third dielectric 123 remains over third conductive pattern 133 and forms a floor of trace groove(s) 1232 and pad groove(s) 1233. In some examples, the thickness of third dielectric 123 can range from about 0.5 μm to about 20 μm.

FIG. 2K shows a cross-sectional view of electronic device 100 at a later stage of manufacture. In the example shown in FIG. 2K, fourth conductive pattern 134 can be provided over third dielectric 123. Fourth conductive pattern 134 can be located in and/or fill openings 1231, trace groove(s) 1232, and pad groove(s) 1233. In accordance with various examples, the elements, features, materials, or manufacturing methods of fourth conductive pattern dielectric 134 can be similar to or the same as those of first conductive pattern 131. In some examples, fourth conductive pattern 134 can initially be disposed over the uppermost side of third dielectric 123. The portions of fourth conductive pattern 134 over the uppermost side of third dielectric 123 can be removed through a planarization process (e.g., using CMP). After planarization, the upper side of fourth conductive pattern 134 and the upper side of third dielectric 123 can be coplanar.

Fourth conductive pattern 134 can comprise or be referred to as traces, pads, vias, ground plane(s), wiring pattern(s), or circuit pattern(s). In accordance with various examples, the portions of fourth conductive pattern 134 that are located in openings 1231 can be coupled to and can contact third conductive pattern 133 (e.g., the upper sides of pads 133a). The portions of fourth conductive pattern 134 disposed in openings 1231 can comprise or be referred to as conductive vias 134a. The thickness of conductive vias 134a can be similar or equal to the thickness of third dielectric 123. In some examples, one or more of the trace groove(s) 1232 and the portion(s) of fourth conductive pattern 134 located in the trace groove(s) 1232 can comprise and/or form one or more ground plane(s).

FIG. 2L shows a cross-sectional view of electronic device 100 at a later stage of manufacture. In the example shown in FIG. 2L, fourth dielectric 124 and fifth conductive pattern 135 are provided over third dielectric 123 and fourth conductive pattern 134. In accordance with various examples, the elements, features, materials, or manufacturing methods of fourth dielectric 124 and fifth conductive pattern 135 can be similar to or the same as those of second dielectric 122 and second conductive pattern 132, respectively. For example, fourth dielectric 124 and fifth conductive pattern 135 can be formed in a manner similar to or the same as that of second dielectric 122 and second conductive pattern 132, as shown in FIGS. 2D, 2E and 2F. Fifth conductive pattern 135 can include conductive vias 135a and traces 135b. In some examples, traces 135b can be referred to as embedded traces. The upper side of fifth conductive pattern 135 can be recessed relative to the upper side of fourth dielectric 124.

FIG. 2M shows a cross-sectional view of electronic device 100 at a later stage of manufacture. In the example shown in FIG. 2M, sixth conductive pattern 136 is provided over fourth dielectric 124 and conductive vias 135a, and fifth dielectric 125 is provided over fourth dielectric 124, fifth conductive pattern 135, and sixth conductive pattern 136. In accordance with various examples, the elements, features, materials, or manufacturing methods of fifth dielectric 125 and sixth conductive pattern 136 can be similar to or the same as those of third dielectric 123 and third conductive pattern 133, respectively. For example, sixth conductive pattern 136 can be formed in a manner similar to or the same as that of third conductive pattern 133, as shown in FIGS. 2G, 2H and 2I, and fifth dielectric 125 can be formed in a manner similar to or the same as that of third dielectric 123, as shown in FIG. 2J. Sixth conductive pattern 136 can include conductive pads 136a and traces 136b. Pads 136a can be coupled to and can contact the upper side of first conductive pattern 135 (e.g., the upper side of vias 135a). The thickness of conductive pad 136a can be greater than the thickness of traces 136b, as conductive pad 136a extends into fourth dielectric 124 to contact and couple to conductive via 135a.

In some examples, traces 136b of sixth conductive pattern 136 may be located between and generally staggered vertically relative to traces 135b of fifth conductive pattern 135. The distance between the lower side of traces 136b and the upper side of traces 135b can be similar to or the same as distance D in FIG. 2I. Traces 136b can be substantially non-overlapping with traces 135b.

Traces 136b and 135b located laterally between each other and separated vertically can increase integration and density of the conductive patterns in some examples. Increasing the density using the above-described staggering techniques can decrease package thickness as compared to packages with the same number of redistribution layers (e.g., two redistribution layers and a ground plane layer) without staggering. Some examples using the staggered traces described herein can increase the number of redistribution layers as compared to packages having same or similar dimensions but without staggering.

Fifth dielectric 125 can cover fourth dielectric 124, fifth conductive pattern 135, and sixth conductive pattern 136. Fifth dielectric 125 can extend into fourth dielectric 124 and contact the upper sides of traces 135b. Fifth dielectric can include apertures 1251 exposing conductive pad 136a.

FIG. 2N shows a cross-sectional view of electronic device 100 at a later stage of manufacture. In the example shown in FIG. 2N, outward terminals 130b are provided in apertures 1251 of fifth dielectric 125, and interconnects 140 are provided on outward terminals 130b.

In accordance with various examples, outward terminal 130b can fill aperture 1251 of fifth dielectric 125. Outward terminals 130b are coupled to and can contact conductive pads 136a. In accordance with various examples, the elements, features, materials, or manufacturing methods of outward terminals 130b can be similar to or the same as those of first conductive pattern 131 and/or third conductive pattern 133. For example, outward terminals 130b can be formed by electroless plating, electrolytic plating, sputtering, PVD, CVD, MOCVD, ALD, LPCVD, PECVD, or any other suitable deposition process and can comprise conductive material such as Cu, Al, Au, Ag, or Ni. Outward terminals 130b can include a seed, similar to seed 131s. In some examples, a mask similar to mask 1 in FIG. 2H can be provided when forming the conductive material of outward terminals 130b.

Interconnects 140 are coupled to and can contact outward terminals 130b. In some examples, interconnects 140 can comprise tin (Sn), Ag, lead (Pb), Cu, Sn—Pb, Sn37-Pb, Sn95-Pb, Sn—Pb—Ag, Sn—Cu, Sn—Ag, Sn—Au, Sn—Bi, or Sn—Ag—Cu. For example, interconnects 140 can be provided by forming a conductive material including solder on outward terminals 130b through a ball drop and reflow process. In some examples, interconnects 140 may also include under bump metals (UBMs) formed between the bump and outward terminal 130b. Interconnects 140 can comprise or be referred to as conductive balls such as solder balls, conductive pillars such as copper pillars, or conductive posts with a solder cap formed on a copper pillar. In some examples, interconnects 140 can be referred to as external input/output terminals of electronic device 100. In some examples, electronic device 100 can be a land grid array (LGA) with component outward terminals 130b serving as external input/output terminals of electronic device 100 (i.e., electronic device 100 can be devoid of component interconnects 140).

In accordance with various examples, dielectric structure 120 and conductive structure 130 can be referred to as RDL substrate 11. In some examples, each conductive and dielectric layer of an RDL substrate 11 can have a minimum thickness of about 1 μm. In some examples, the overall thickness of RDL substrate 11 can range from about 16 μm to 200 μm.

Although conductive structure 130 is shown as having a total of seven layers including first conductive pattern 131, second conductive pattern 132, third conductive pattern 133, fourth conductive pattern 134, fifth conductive pattern 135, sixth conductive pattern 136, and outward terminals 130b, the number of conductive pattern layers can be fewer or greater than seven, with conductive structure 130 having at least one conductive pattern having traces formed using a semi-additive process, similar to third conductive pattern 133 and sixth conductive pattern 136, and one conductive pattern having traces formed as embedded traces, similar to second conductive pattern 132 and fifth conductive pattern 135. For example, a set of conductive pattern traces of conductive structure 130 can be formed in grooves provided in the dielectric (i.e., embedded traces), and a set of conductive pattern traces can be formed, and then the dielectric can be subsequently deposited over the formed conductive pattern traces (i.e., SAP traces).

In accordance with various embodiments, after interconnects 140 are provided, a singulation process can be performed to separate substrate 102 into individual electronic devices 100. The singulation process can include sawing through RDL substrate 11 and between adjacent electronic components 110 (e.g., sawing through saw streets S). The singulation process can utilize a blade, laser beam, or any other suitable cutting means. After singulation, the lateral sides of RDL substrate 11 can be coplanar with the lateral sides of electronic component 110.

Electronic device 100 incorporating staggered, substantially non-overlapping traces can have a greater density of signal traces than a similarly sized package without staggered traces. Traces located laterally between each other and separated vertically (i.e., staggered traces) can support increased integration and density of the conductive patterns. Increasing the density using the above-described staggering techniques can decrease package thickness as compared to packages with the same number of redistribution layers (e.g., two redistribution layers and a ground plane layer) without staggering. Some examples using the staggered traces can increase the number of redistribution layers as compared to packages having same or similar dimensions but lacking staggered traces.

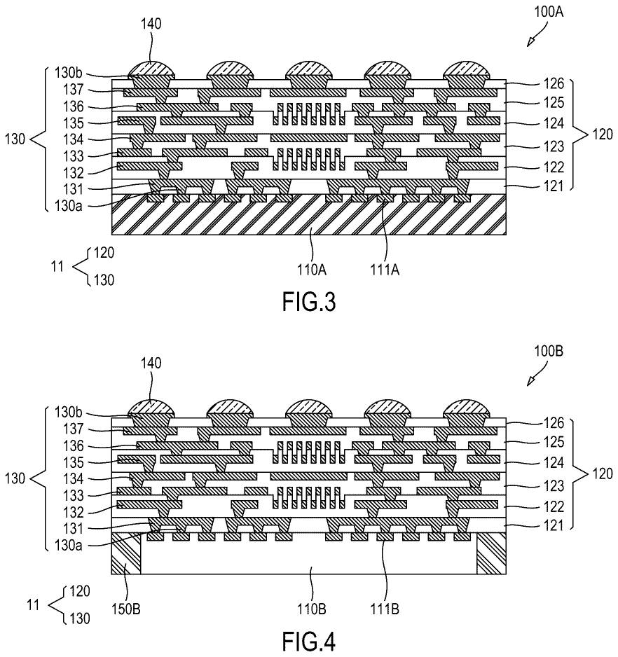

FIG. 3 shows a cross-sectional view of an example electronic device 100A. In the example shown in FIG. 3, electronic device 100A can comprise electronic component 110A, RDL substrate 11, and interconnects 140. Electronic component 110A includes component interconnects 111a. RDL substrate 11 includes dielectric structure 120 and conductive structure 130. In some examples, electronic device 100A can be manufactured in a process similar to the process shown in FIGS. 2A to 2N described above.

Electronic device 100A can include seventh conductive pattern 137 and sixth dielectric 126. Sixth dielectric 126 can have elements, features, materials, or manufacturing methods similar to or the same as those of second dielectric 122. Seventh conductive pattern 137 can have elements, features, materials, or manufacturing methods similar to or the same as those of second conductive pattern 132. In some examples, electronic device 100A can comprise or be referred to as a wafer level package (WLP) or wafer level chip scale package (WLCSP).

FIG. 4 shows a cross-sectional view of an example electronic device 100B. In the example shown in FIG. 4, electronic device 100B comprises electronic component 110B, RDL substrate 11, interconnects 140, and encapsulant 150B. RDL substrate 11 includes dielectric structure 120 and conductive structure 130. Electronic component 110B can comprise component interconnects 111B. Electronic device 100B shown in FIG. 4 can be similar to electronic device 100A shown in FIG. 3, but with encapsulant 150B provided around electronic device 100B, and can be manufactured in a process similar to the process shown in FIGS. 2A to 2N described above. For example, substrate 102 in FIGS. 2A to 2N can comprise a reconstituted wafer having encapsulant 150B provided between adjacent electronic components 110B. In some examples, singulation, as shown in FIG. 2N, can take place through encapsulant 150B, such that after singulation, encapsulant 150B is coplanar with RDL substrate 11.

In some examples, encapsulant 150B can comprise or be referred to as a package body, an encapsulating structure, a mold, an epoxy molding compound, a resin, a filler-reinforced polymer, a B-stage compressed film, or gel. Encapsulant 150B can be provided by transfer molding, compression molding, liquid encapsulant molding, vacuum lamination, paste printing, film assisted molding, or other processes as known to one of ordinary skill in the art. In some examples, encapsulant 150B can contact or cover a bottom side and/or lateral sides of electronic component 110B. In some examples, the bottom side of encapsulant 150B and the bottom side of electronic component 110B can be coplanar, and the bottom side of electronic component 110B can be exposed from the bottom side of encapsulant 150B. Encapsulant 150B can protect electronic component 110B from the external environment or from environmental exposure.

In some examples, RDL substrate 11 can be provided on the top side of encapsulant 150B as well as on the top side of electronic component 110B. In some examples, the top side of electronic component 110B and the top side of encapsulant 150B can be coplanar. In some examples, electronic device 100B can comprise or be referred to as a wafer level fan-out (WLFO).

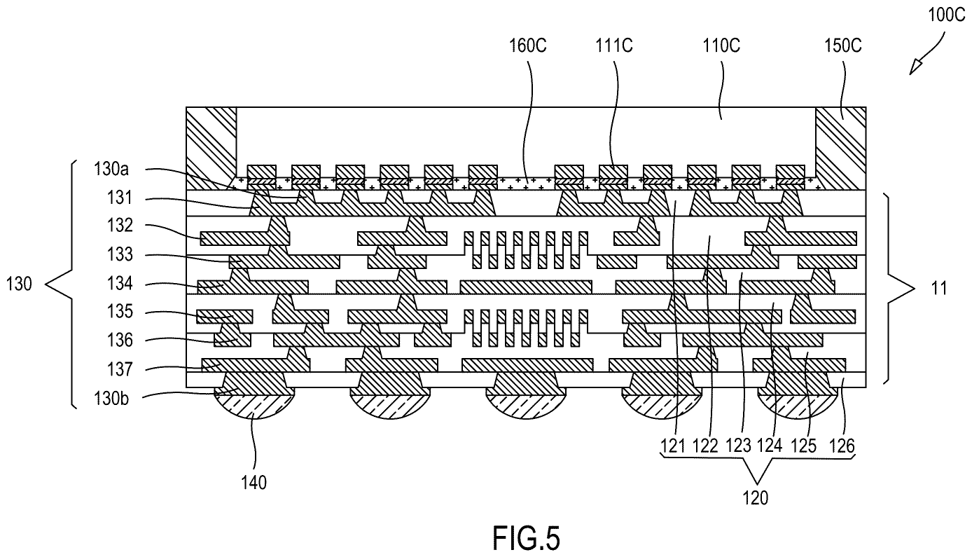

FIG. 5 shows a cross-sectional view of an example electronic device 100C. In the example shown in FIG. 5, electronic device 100C can comprise electronic component 110C, RDL substrate 11, interconnects 140, and encapsulant 150C. In some examples, electronic device 100C can also include underfill 160C. RDL substrate 11 includes dielectric structure 120 and conductive structure 130. Electronic device 100C shown in FIG. 5 can be similar to electronic devices 100A and 100B shown in FIGS. 3 and 4, respectively, but with dielectric structure 120 and conductive structure 130 can be provided prior to coupling electronic component 110C to RDL substate 11 and providing encapsulant 150C.

FIGS. 6A to 6E show cross-sectional views of an example method for manufacturing an electronic device, such as electronic device 100C of FIG. 5. FIG. 6A shows a cross-sectional view of electronic device 100C at an early stage of manufacture. In the example shown in FIG. 6A, RDL substrate 11, including dielectric structure 120 and conductive structure 130, can be provided on carrier 202. In accordance with various examples, RDL substrate 11 can be provided over carrier 202 using a method similar to or the same as that shown in FIGS. 2A to 2N.

In some examples, carrier 202 can comprise or be referred to as a wafer, plate, panel, strip, substrate, or temporary carrier. Carrier 202 can comprise semiconductor material (e.g., Si), glass, metal, ceramic, etc. In some examples, a temporary adhesive can be provided on the upper side of carrier 202 to facilitate the separation of RDL substrate 11 from carrier 202. The temporary adhesive can be, for example, a heat release tape (or film) or an optical release tape (or film), configured to have its adhesive strength reduced by heat or light, respectively.

FIG. 6B shows a cross-sectional view of electronic device 100C at a later stage of manufacture. In the example shown in FIG. 6B, support carrier 220 is coupled to an upper side of RDL substrate 11 and carrier 202 is removed from the opposite side of RDL substrate 11.

Support carrier 220 can comprise or be referred to as a wafer, plate, panel, strip, substrate, or temporary carrier. Support carrier 220 can comprise semiconductor material (e.g., Si), glass, metal, ceramic, etc. In some examples, a temporary adhesive 222 can be provided on support carrier 220 to facilitate the separation of RDL substrate 11 from support carrier 220. Temporary adhesive 222 can be, for example, a heat release tape (or film) or an optical release tape (or film), configured to have its adhesive strength reduced by heat or light, respectively. In some examples, sixth dielectric 126 and outward terminals 130b of conductive structure 130 can be coupled to and/or contact temporary adhesive 222.

In accordance with various examples, carrier 202 (FIG. 6A) can be removed from RDL substrate 11 by grinding, etching, laser ablation, physical force, application of heat and/or light, or another suitable removal method. Removal of carrier 202 exposes a bottom side of conductive vias 131a and first dielectric 121. In some examples, removal of carrier 202 can exposes inward terminals 130a of conductive structure 130. In other examples, and as shown in FIG. 6C, inward terminals 130a can be provided after removal of carrier 202.

FIG. 6C shows a cross-sectional view of electronic device 100C at a later stage of manufacture. In the example shown in FIG. 6C, RDL substrate 11 can be flipped, relative to the view shown in FIG. 6B, and electronic component 110C is provided over RDL substrate 11. Electronic component 110C can comprise or be referred to as a die, chip, package (e.g., one or more die in encapsulant and/or coupled to a laminate or RDL substrate), or passive element. In some examples, the thickness of electronic component 110C can range from about 20 μm to about 1000 μm.

In accordance with examples, electronic component 110C can be coupled to conductive structure 130. For example, component interconnects 111C of electronic component 110C can be coupled to and/or contacting inward terminals 130A of conductive structure 130. Component interconnects 111C can comprise or be referred to as bumps, pads, or pillars. In some examples, the thickness of component interconnect 111C can range from about 1 μm to about 10 μm. In some examples, component interconnects 111C can be electrically coupled to substrate inward terminals 130a via solder. In some examples, component interconnect 111C can be electrically coupled to inward terminals 130a by thermocompression bonding, ultrasonic bonding, laser assisted bonding, or hybrid bonding (e.g., the interconnection between component interconnect 111C and inward terminal 130a can be solderless). In some examples, the elements, features, materials, or manufacturing methods of inward terminals 130A can be similar to or the same as those of third conductive pattern 133.

In accordance with various examples, underfill 160C can be provided between RDL substrate 11 and electronic component 110C. In some examples, underfill 160C can contact RDL substrate 11 (e.g., dielectric structure 120 or conductive structure 130), component interconnect 111C, and electronic component 110C. In some examples, underfill 160C can comprise or be referred to as capillary underfill, non-conductive paste, or non-conductive film. In some examples, underfill 160C can be inserted into a gap between electronic component 110C and RDL substrate 11 after electronic component 110C is electrically coupled to RDL substrate 11. In some examples, underfill 160C can be pre-coated onto RDL substrate 11 prior to electronic component 110C being coupled to RDL substrate 11. In some examples, underfill 160C can be pre-coated on electronic component 110C prior to electronic component 110C being coupled to RDL substrate 11. In some examples, a curing process (e.g., a thermal curing process or a photocuring process) of underfill 160C can be performed.

FIG. 6D shows a cross-sectional view of electronic device 100C at a later stage of manufacture. In the example shown in FIG. 6D, encapsulant 150C is provided over electronic component 110C and RDL substate 11. In some examples, encapsulant 150C can cover and/or contact RDL substrate 11, electronic component 110C, and underfill 160C. In some examples, underfill 160C can be omitted, and encapsulant 150C can be filled between electronic component 110C and RDL substrate 11. In some examples, encapsulant 150C can be removed from over the backside of electronic component 110C. For example, the backside of electronic component 110C can be exposed from encapsulant 150C. In some embodiments, the backside of electronic component 110C and encapsulant 150C can be coplanar. In some embodiments, encapsulant 150C can cover the backside of electronic component 110C. Elements features, materials, or manufacturing methods of encapsulant 150C can be similar to or the same as those of encapsulant 150B.

FIG. 6E shows a cross-sectional view of electronic device 100C at a later stage of manufacture. In the example shown in FIG. 6E, support 252 is coupled to encapsulant 150C and electronic component 110C, and support carrier is removed from RDL substrate 11.

In accordance with various examples, support 252 can comprise or be referred to as a wafer, plate, panel, strip, substrate, tape, or temporary carrier. In some examples, a temporary adhesive can be provided on the upper side of support 252 to facilitate the separation of support 252 from electronic device 100C. The temporary adhesive can be, for example, a heat release tape (or film) or an optical release tape (or film), configured to have its adhesive strength reduced by heat or light, respectively.

In accordance with various examples, support carrier 220 (FIG. 6D) can be removed from RDL substrate 11 by grinding, etching, laser ablation, physical force, application of heat and/or light, or another suitable removal method. Removal of support carrier 220 exposes outward terminals 130b and sixth dielectric 126. Interconnects 140 can be provided on outward terminals 130b, as described above with refence to FIG. 2N.

In accordance with various embodiments, after interconnects 140 are provided, a singulation process can be performed to separate RDL substrates 11 with electronic components 110C coupled thereto into individual electronic devices 100C. The singulation process can include sawing through RDL substrate 11 and encapsulant 150C (e.g., sawing along saw lines X). The singulation process can utilize a blade, laser beam, or any other suitable cutting means. After singulation, the lateral sides of RDL substrate 11 can be coplanar with the lateral sides of encapsulant 150C. In some examples, the singulation process can remove encapsulant 150C from the lateral sides of electronic component 110C, such that after singulation, the lateral sides of RDL substrate 11 are coplanar with the lateral sides of electronic component 110C.

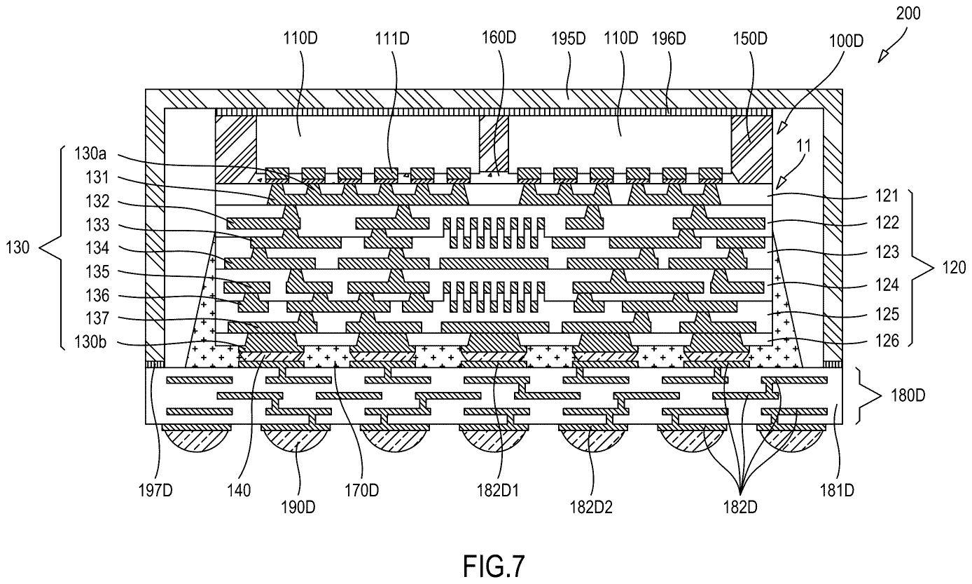

FIG. 7 shows a cross-sectional view of an example electronic device 200. In the example shown in FIG. 7, electronic device 200 can comprise electronic device 100D, underfill 170D, base substrate 180D, external interconnect 190D, and cap 195D. Electronic device 100D can be coupled to base substrate 180D and can comprise electronic components 110D, RDL substrate 11, component interconnects 111D, interconnects 140, encapsulant 150D, and underfill 160D. RDL substrate 11 can include dielectric structure 120 and conductive structure 130. In accordance with various examples, electronic device 100D can be similar to electronic device 100C in FIG. 5 and can be provided as shown in FIGS. 6A to 6E.

In accordance with various examples, interconnects 140 of electronic device 100D are coupled to base substrate 180D. Base substrate 180D can comprise dielectric structure 181D and conductive structure 182D. In some examples, dielectric structure 181D can comprise dielectric layers. The dielectric layers can comprise one or more layers of dielectric materials interleaved with the layers of the conductive structures. In some examples, the dielectric materials can comprise PI, BCB, PBO, resin, or Ajinomoto Buildup Film (ABF). In some examples, conductive structure 182D can comprise one or more conductive layers defining signal distribution elements (e.g., traces, vias, pads, conductive paths, or UBM). Conductive structure 182D can comprise substrate inward terminal 182D1 and substrate outward terminal 182D2. In some examples, substrate inward terminal 182D1 can comprise pads, lands, UBM, or studs. In some examples, substrate outward terminals 182D2 can comprise pads or lands. External interconnects 190D can comprise solder balls, bumps, pad, or pillar. In some examples, electronic device 200 can be an LGA (e.g., external interconnects 190D can be omitted).

In some examples, base substrate 180D can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising bismaleimide triazine (BT) or a flame retardant laminate (FR4), and dielectric and conductive layers can be formed on the permanent core structure. In other examples, the pre-formed substrate can be a coreless substrate omitting the permanent core structure, and the dielectric and conductive layers can be formed on a sacrificial carrier that can be removed after formation of the dielectric and conductive layers and before attachment to the electronic device. The pre-formed substrate can be referred to as a printed circuit board (PCB) or a laminate substrate.

In some examples, substrate 180D can be an RDL substrate. RDL substrates can comprise one or more conductive redistribution layers and one or more dielectric layers and (a) can be formed layer by layer over an electronic device to where the RDL substrate is to be electrically coupled, or (b) can be formed layer by layer over a carrier and can be entirely removed or partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution pattern or traces configured to collectively (a) fan-out electrical traces outside the footprint of the electronic device, and/or (b) fan-in electrical traces within the footprint of the electronic device. The conductive pattern can be formed using a plating process such as, for example, an electroplating process or an electroless plating process. The conductive pattern can comprise an electrically conductive material such as, for example, copper or other plateable metal. The locations of the conductive pattern can be made using a photo-patterning process such as, for example, a photolithography process and a photoresist material to form a photolithographic mask. The dielectric layers of the RDL substrate can be patterned with a photo-patterning process, and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), and/or SiON. In some examples, the inorganic dielectric layer(s) can be formed by growing the inorganic dielectric layers using an oxidation or nitridization process instead of using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising BT or FR4 and these types of RDL substrates can be referred to as a coreless substrate.

Interconnects 140 of electronic device 100D can be electrically coupled to substrate inward terminal 182D1 of base substrate 180D. In some examples, interconnects 140 can be electrically coupled to substrate inward terminal 182D1 by thermal compression bonding, ultrasonic bonding, laser assisted bonding, or hybrid bonding. In some examples, solder can be interposed between interconnects 140 and substrate inward terminal 182D1. In some examples, underfill 170D can be interposed between RDL substrate 11 and base substrate 180D. Elements, features, materials, or manufacturing methods of underfill 170D can be similar to or the same as those of underfill 160C.

In some examples, cap 195D can be attached through adhesive material 197D to substrate 180D and can be attached through cap attach material 196D to electronic components 110D. In some examples, cap attach material 196D can also be interposed between encapsulant 150D and cap 195D. Cap attach material 196D comprise or be referred to as thermal interface material (TIM) (e.g., a metallic TIM or polymer TIM), an adhesive, or a backside metallization. Cap 195D can comprise or be referred to as a heat spreader, lid, cover, case, shield, or housing. In some examples, cap 195D can comprise a metal or metal alloy (e.g., Cu, Al, Ni, Ag, etc.). In some examples, the thickness of cap 195D can range from about 100 μm to about 1000 μm. Cap 195D can dissipate heat from electronic components 110D, can shield electronic component 110D from electromagnetic interference, and/or protect RDL substrate 11 and electronic component 110D from the external environment.

Electronic devices using staggered, substantially non-overlapping traces can reduce manufacturing costs by reducing a number of steps used to make similar structures. A hybrid process can be used by embedding a lower trace then staggering a substantially non-overlapping upper trace using a semi-additive process. The hybrid process can use fewer steps, which can decrease manufacturing time and costs. Staggered, substantially non-overlapping traces can increase integration and density of the conductive patterns. Increasing the density can decrease package thickness for the same number of traces. Increasing the density can also increase the number of redistribution layers in similarly sized packages.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate;
a first dielectric disposed over the substrate, the first dielectric defining first trace openings;
a first conductive pattern disposed in the trace openings and recessed from an upper side of the first dielectric, the first conductive pattern comprising first traces;
a second conductive pattern disposed over the upper side of the first dielectric, the second conductive pattern comprising second traces staggered over the first traces; and
a second dielectric disposed over the second conductive pattern and extending to the first traces in the trace openings.

2. The electronic device of claim 1, wherein the first dielectric defines openings lateral to the trace openings and extending through the first dielectric, wherein the first conductive pattern comprises first conductive vias disposed in the openings and recessed from the upper side of the first dielectric.

3. The electronic device of claim 2, wherein the second conductive pattern comprises conductive pads coupled to the first conductive vias.

4. The electronic device of claim 3, wherein the second dielectric is disposed over the conductive pads.

5. The electronic device of claim 1, wherein the first traces are embedded in the first dielectric.

6. The electronic device of claim 1, wherein the second traces are formed over the first dielectric using a semi-additive process before the second dielectric is provided.

7. The electronic device of claim 1, further comprising a seed layer disposed between the second conductive pattern and the upper side of the first dielectric.

8. The electronic device of claim 1, further comprising:
a third dielectric disposed between the first dielectric and the substrate, the third dielectric defining a ground opening; and
a third conductive pattern in the ground opening, the third conductive pattern comprising a ground plane disposed between the first traces and the substrate.

9. The electronic device of claim 1, wherein the substrate comprises an electronic component including component interconnects electronically coupled to the first conductive pattern.

10. The electronic device of claim 9, further comprising an underfill disposed between the electronic component and the first dielectric.

11. An electronic device, comprising:
a substrate;
a first dielectric disposed over the substrate, the first dielectric defining first trace openings;
a first conductive pattern disposed in the first trace openings and recessed from an upper side of the first dielectric, the first conductive pattern comprising first traces;
a second conductive pattern disposed over the upper side of the first dielectric, the second conductive pattern comprising second traces staggered over the first traces;
a second dielectric disposed over the second conductive pattern and extending to the first conductive pattern in the trace openings;
a third dielectric disposed over the second dielectric, the third dielectric defining second trace openings;
a third conductive pattern disposed in the second trace openings and recessed from an upper side of the third dielectric, the third conductive pattern comprising third traces;
a fourth conductive pattern disposed over the upper side of the third dielectric, the fourth conductive pattern comprising fourth traces staggered over the third traces; and
a fourth dielectric disposed over the fourth conductive pattern and extending to the third traces in the trace openings.

12. The electronic device of claim 11, further comprising a fifth conductive pattern disposed in a ground opening defined by second dielectric, the fifth conductive pattern comprising a ground plane between the second traces and the third traces.

13. The electronic device of claim 11, further comprising an outward terminal disposed in an opening defined in the fourth dielectric.

14. A method of manufacturing an electronic device, comprising:
providing a substrate;
providing a first dielectric over the substrate, the first dielectric defining first trace openings;
providing a first conductive pattern in the first trace openings, wherein the first conductive pattern is recessed from an upper side of the first dielectric, the first conductive pattern comprising first traces;
providing a second conductive pattern over the upper side of the first dielectric, the second conductive pattern comprising second traces staggered over the first traces; and
providing a second dielectric over the second conductive pattern, wherein the second dielectric extends to the first traces in the first trace openings.

15. The method of claim 14, wherein providing the second conductive pattern further comprises:
providing a seed layer over the first dielectric;
providing a mask over the first conductive pattern, wherein the seed layer over the first dielectric is exposed by a second trace opening defined by the mask;
providing the second conductive pattern in the opening; and
removing the mask.

16. The method of claim 14, wherein the first traces are provided as embedded traces.

17. The method of claim 14, wherein the second traces are provided using a semi-additive process before the second dielectric is provided.

18. The method of claim 14, further comprising:
providing a third dielectric over the substrate, the third dielectric defining a ground opening; and
providing a third conductive pattern in the ground opening, the third conductive pattern comprising a ground plane.

19. The method of claim 14, further comprising:
providing a third dielectric disposed over the second dielectric, the third dielectric defining second trace openings;
providing a third conductive pattern disposed in the second trace openings and recessed from an upper side of the third dielectric, the third conductive pattern comprising third traces;
providing a fourth conductive pattern disposed over the upper side of the third dielectric, the fourth conductive pattern comprising fourth traces staggered over the third traces; and
providing a fourth dielectric disposed over the fourth conductive pattern and extending to the third traces in the second trace openings.

20. The method of claim 14, further comprising providing a ground plane in an opening defined by the second dielectric and over the second conductive pattern.
